(19) United States
(12) Patent Application Publication
(10) Pub. No.: US 2004/0119101 A1
(43) Pub. Date: Jun. 24, 2004

(54) Contact layout for MOSFETs under tensile strain

(76) Inventors: Gerhard Schrom, Hillsboro, OR (US); Mark A. Armstrong, Portland, OR (US); Mohamed A. Arafa, Chandler, AZ (US)

Correspondence Address: Edwin H. Taylor, BLAKELY, SOKOLOFF, TAYLOR & ZAFMAN LLP, Seventh Floor, 12400 Wilshire Boulevard, Los Angeles, CA, 90025-1026, US

(21) Appl. No.: 10/329,078

(22) Filed: Dec. 23, 2002

(51) Int. Cl. H01L 27/10

(52) U.S. Cl. 257/206

(57) ABSTRACT

A method for improving performance of a transistor oriented in <110> orientation is described. Contacts on either side of the gate are misaligned with respect to one another. The placement of the contacts changes the stress pattern so that the direction of a large part of the tensile strain is diverted from the direction of the current flow.

### FIELD OF THE INVENTION

The present invention pertains to the field of integrated circuit design in a CMOS process. More particularly, the present invention relates to a method of placing contacts to improve NMOS channel current without degrading PMOS channel current.

### BACKGROUND OF THE INVENTION

An integrated circuit (IC) is typically processed on a single crystal of silicon. Complementary Metal Oxide Silicon (CMOS) is one technology used to build IC's. Other technologies include silicon bipolar technology, Gallium Arsenide technology, and Josephson junction technology.

A transistor is the basic device used to implement a function on an integrated circuit. Transistors in CMOS technology are created using a Metal-Oxide-Silicon (MOS) structure by superimposing several layers of conducting and insulating materials in a photolithographic process. A transistor created in CMOS technology is known as a MOS field-effect transistor (MOSFET). A transistor having a p-doped silicon substrate separating two areas of n-type silicon is known as an n-type transistor or NMOS transistor. A transistor having a n-doped silicon substrate separating two areas of p-type silicon is known as a p-type transistor or PMOS transistor.

In a typical CMOS process, MOSFETs are oriented such that the current flows in the <110> directions of the silicon crystal. FIG. 1 depicts a diagram of a CMOS transistor fabricated on a substrate 100. Diffusion 110 and diffusion 115 are portions of a silicon substrate 100 that have been doped with a controlled amount of impurity atoms so that they are either n-type or p-type regions. Diffusion areas 110 and 115 are also known as the source and the drain regions respectively. Between the diffusion areas 110 and 115 is a channel, which is covered by a thin insulating layer of silicon dioxide called the gate oxide. Deposited over this oxide is a conducting gate electrode 120.

The layers of insulators above the gate create a compressive stress on the MOSFET. The compressive stress causes tensile strain under the gate 120. Contacts 130-135 placed opposite to each other on either side of the gate 120 help to relieve the tensile strain locally. However, stress and strain patterns still exist. This tensile strain 140 is parallel to the direction of channel current flow 150. Tensile strain 140 has been shown to increase the NMOS channel current due to increased electron mobility and to reduce PMOS channel current due to reduced hole mobility. A higher channel current helps to improve the performance of the device. The channel current is often used to drive another device coupled to the MOSFET. Thus, a MOSFET device having an increased NMOS channel current without degrading the PMOS channel current is desired.

### BRIEF DESCRIPTION OF THE DRAWINGS

The embodiments of the present invention are illustrated by way of example and not in the figures of the accompanying drawings, in which like references indicate similar elements and in which:

FIG. 1 is a prior art CMOS transistor design;

FIG. 2 is one embodiment of a CMOS transistor having increased NMOS channel current without degrading the PMOS channel current;

FIG. 3 is a graph of n-type and p-type silicon piezoresistivity under tensile stress as a function of the angle between the stress and the current flow; and

FIG. 4 is an embodiment of two PMOS transistors in series having staggered contacts.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

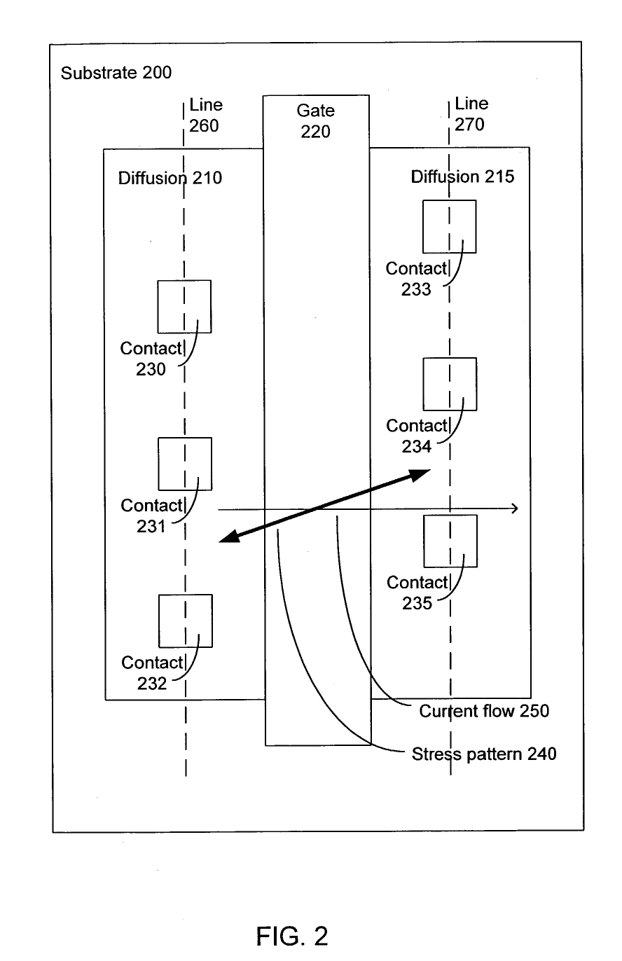

FIG. 2 depicts a CMOS transistor having a first diffusion 210 and a second diffusion 215 in substrate 200. The first diffusion 210 and second diffusion 215 may be doped using p-type or n-type dopants.

A channel in the substrate 200 separates the first diffusion 210 from the second diffusion 215. An insulating layer of silicon dioxide may be deposited on the channel. The insulating layer is covered with a gate electrode 220. The gate may be a polycrystalline polysilicon. Layers of dielectric material are later placed on top of the transistor to help route interconnects. The layers of dielectric material may cause tensile strain under the gate.

Contacts are placed on both sides of the gate 220 in and on the diffusion 210 and the diffusion 215. Contacts 230-235 are formed in alignment on each side of the gate 220 as shown by lines 260 and 270 such that they are parallel to the gate 220. Each contact on a given side of the gate has a space or gap between the next contact on that side. For example, there is a gap between contacts 233 and 234. Although the diagram of FIG. 2 depicts only three contacts per side, each side of the gate is not limited to three contacts. More than one contact is often used on larger transistors.

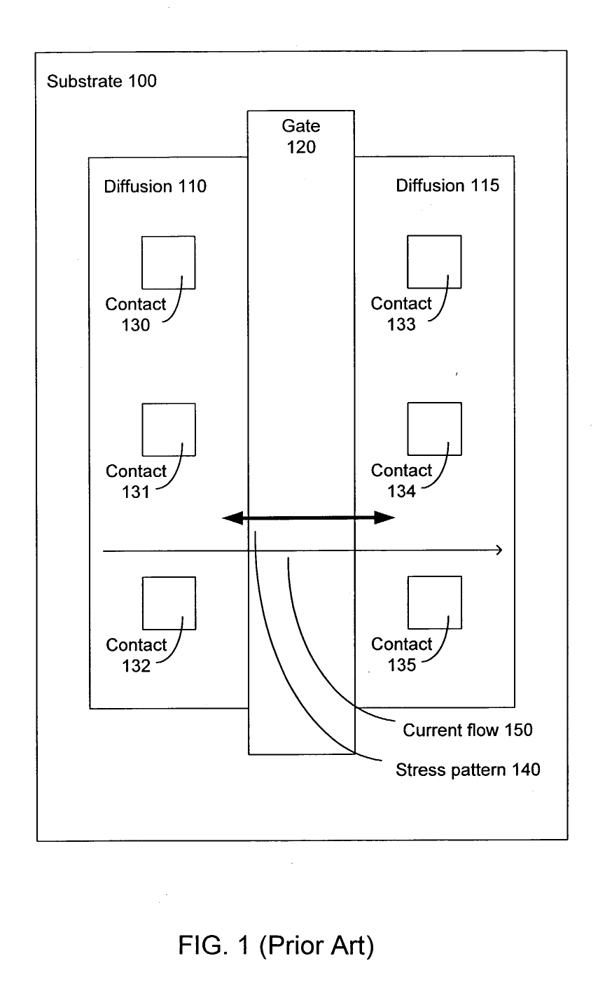

For this embodiment of the invention, contacts on one side of the gate are staggered with respect to contacts on the other side of the gate. In other words, the contacts on one side of the gate 220 are opposite to the gaps between contacts of the other side of the gate. Thus, the contacts on the source and drain regions are not mirror images of each other. For example, the contact 230 is placed opposite to the gap between contacts 233 and 234. This misaligned placement of contacts 230-235 changes the stress pattern 240 when compared to that of the stress pattern 140 of FIG. 1. The tensile strain 240 of FIG. 2 is diverted from the direction of current flow 250. In this example, the angle between the stress pattern 240 and current flow 250 is approximately 45 degrees. The angle between the stress pattern 240 and the current flow 250 may be further increased by increasing the spacing between the contacts.

For another embodiment of the invention, a CMOS transistor may have only one contact placed on each side of the gate 220. Thus, a first contact is placed in and on the diffusion 210 and a second contact is placed in and on the diffusion 215. The contacts may be placed such that the first contact in and on the diffusion 210 is offset with respect to the second contact in and on the diffusion 215. This offset placement of contacts changes the stress pattern of the transistor with respect to that of the stress pattern 140 of FIG. 1.

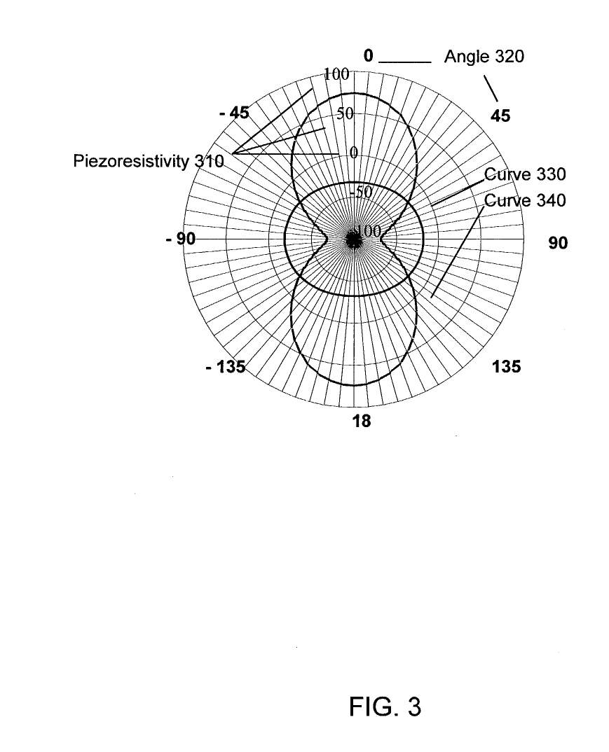

FIG. 3 depicts a graph of the piezoresistivity of n-type and p-type silicon under tensile stress as a function of the angle between the stress pattern 240 and the current flow 250 in the <110> directions. Piezoresistivity is the material property by which resistance changes with applied stress in a material. Channel current is inversely proportional to the resistivity of a material. Thus, the lower the piezoresistivity in an NMOS or PMOS device, the greater the channel current. Each ring 310 of FIG. 3 represents the piezoresistivity of a device, while each line 320 represents the angle between the stress pattern 240 and the current flow 250 of the device.

Curve 330 is the measured piezoresistivity of an NMOS device and curve 340 is the measured piezoresistivity of a PMOS device at a given angle. Curve 340 shows that the piezoresistivity of a PMOS device decreases as the angle between the stress pattern 240 and the current flow 250 increases from zero degrees to approximately 90 degrees. Curve 330 shows that the piezoresistivity of the NMOS device remains approximately the same as the angle changes. Therefore, by increasing the angle the angle between the stress pattern 240 and the current flow 250 from zero to 45 degrees as in FIG. 2, the piezoresistivity of a PMOS device will decrease while the piezoresistivity of an NMOS device will stay substantially the same. As a result, staggering the contacts allow the PMOS channel current to improve.

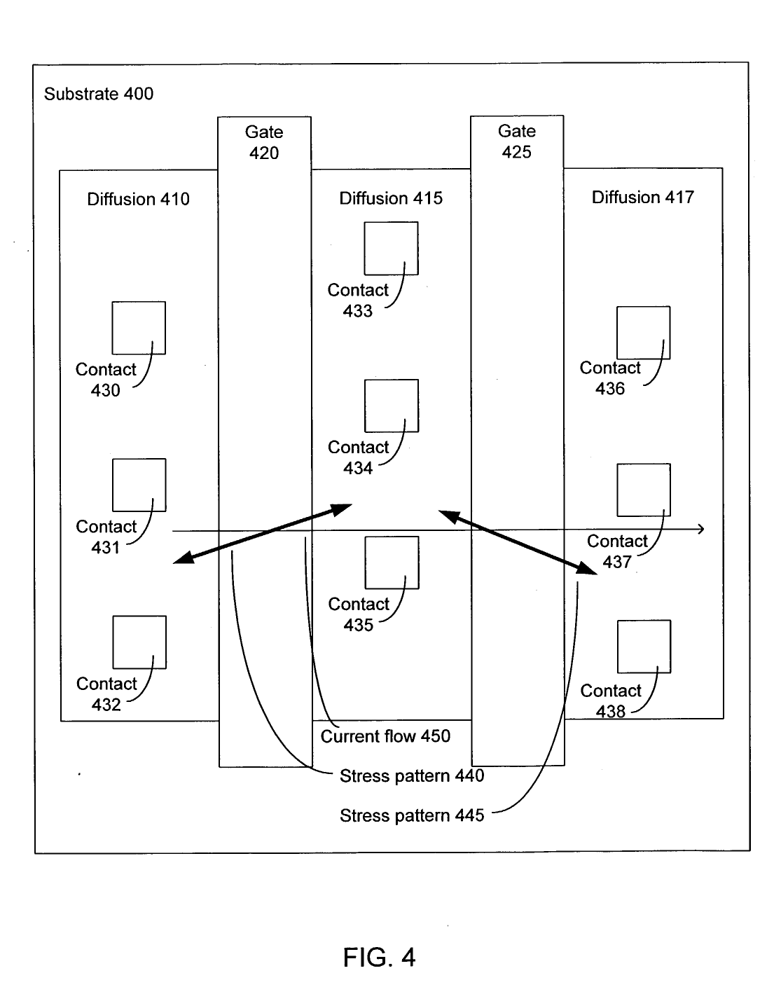

For another embodiment of the invention, FIG. 4 depicts the layout of two PMOS transistors that are connected in series with one another. Both transistors are fabricated on substrate 400. The substrate 400 is doped with a p-type material to form diffusion regions 410, 415, and 417. Diffusion regions 410 and 415 may form the source and drain regions respectively of the first transistor. Diffusion regions 415 and 417 may form the source and drain regions of the second transistor. Thus, the drain of the first transistor and the source of the second transistor in this embodiment share the same diffusion area 415.

The diffusion regions 410, 415, and 417 are coupled to the gate 420 and the gate 425. Gate 420 is the gate of the first transistor, while gate 425 is the gate of the second transistor. Contacts 430-432 are coupled to diffusion 410, contacts 433-435 are coupled to diffusion 415, and contacts 436-438 are coupled to diffusion 417. The contacts 433-435 are placed on diffusion 415 such that each contact is placed to line up with the gaps between the contacts on diffusions 410 and 417. Therefore, the stress patterns 440 and 445 of the first and second transistors are at an angle greater than zero degrees with respect to the current flow 450. As a result, the piezoresistivity of the first and second transistors are lower than the case where the contacts of diffusions 410, 415, and 417 are all lined up with respect to one another. By staggering the contacts of each diffusion region, the channel currents of the first and second PMOS transistors are improved.

In the foregoing specification the invention has been described with reference to specific exemplary embodiments thereof. It will, however, be evident that various modification and changes may be made thereto without departure from the broader spirit and scope of the invention as set forth in the appended claims. The specification and drawings are, accordingly, to be regarded in an illustrative rather than restrictive sense.

What is claimed is:

1. A transistor, comprising:
a drain;
a source;
a gate coupled to the drain and source; and
a plurality of contacts coupled to the drain and source, wherein the plurality of contacts are parallel to the gate, wherein the plurality of contacts have a gap between each other, wherein the contacts coupled to the drain are opposite to the gaps between the contacts coupled to the source.

2. The transistor of claim 1, further comprising:
a plurality of insulating layers coupled to the gate, wherein the gate oxide causes a compressive stress on the transistor.

3. The transistor of claim 1, wherein the transistor is created using Complementary Metal Oxide Silicon (CMOS) technology on a silicon crystal.

4. The transistor of claim 3, wherein the transistor is oriented such that the current flow occurs in a <110> direction on the silicon crystal.

5. The transistor of claim 3, wherein the transistor is an n-type transistor.

6. The transistor of claim 3, wherein the transistor is a p-type transistor.

7. A method, comprising:
doping a first and a second region of a silicon substrate, wherein a channel separates the first and the second region;
covering the channel using an insulating layer;
placing a first and a second contact on the first region; and
placing a third and a fourth contact on the second region, wherein the first and second contacts are misaligned with respect to the third and fourth contacts.

8. The method of claim 7, wherein the silicon substrate is oriented in a <110> direction.

9. The method of claim 7, further comprising:
placing a polycrystalline silicon electrode over the insulating layer.

10. The method of claim 7, wherein the first and the second regions are doped n-type.

11. The method of claim 7, wherein the first and the second regions are doped p-type.

12. The method of claim 9, further comprising:
coupling layers of dielectric material over the channel and the first and second regions, wherein the layers of dielectric material create a compressive stress on the first and the second regions.

13. A method, comprising:
forming a transistor on a silicon crystal, wherein the transistor has a source and a drain, wherein a current of the transistor flows in the <110> direction of the silicon crystal;
placing a first contact and a second contact on the source of the transistor, wherein the first contact and the second contact are separated by a gap; and
placing a third contact and a fourth contact on the drain of the transistor, wherein the third contact and the fourth contact are separated by a gap, wherein the gap between the first and second contacts fall between the third and fourth contacts.

14. The method of claim 13, further comprising:
placing an insulating layer on top of the transistor.

15. An apparatus, comprising:
means for placing a plurality of contacts on an n-type transistor (NMOS) having a channel current;
means for placing a plurality of contacts on a p-type transistor (PMOS) having a channel current; and
means for increasing the channel current of the NMOS without degrading the channel current of the PMOS.

16. The apparatus of claim 15, further comprising:
means for enhancing mobility in a strained silicon with the NMOS and the PMOS in <110> orientation.

17. The apparatus of claim 15, further comprising:
means for changing a stress pattern of the PMOS, wherein the stress pattern causes a tensile strain.

18. The apparatus of claim 17, further comprising:
means for diverting a current flow from the tensile strain.

19. The apparatus of claim 18, further comprising:
means for making the angle between the tensile strain and the current flow approximately 45 degrees.

20. The apparatus of claim 18, further comprising:
means for reducing the resistivity of the PMOS as the angle between the tensile strain and the current flow is increased.

21. A transistor, comprising:
a drain;
a source;
a gate coupled to the drain and source;
a first contact coupled to the drain; and
a second contact coupled to the source, wherein the second contact is offset with respect the first contact to improve a drive current of the transistor.

22. The transistor of claim 21, wherein the transistor is an n-type transistor.
